(19) United States
(12) Patent Application Publication
(10) Pub. No.: US 2015/0255266 A1
(43) Pub. Date: Sep. 10, 2015

(54) ETCHING DEVICE, ETCHING METHOD AND PATTERNING APPARATUS

(71) Applicants: BOE TECHNOLOGY GROUP CO., LTD., Beijing (CN); ORDOS YUANSHENG OPTOELECTRONICS CO., LTD., Ordos (CN)

(72) Inventors: Qun MA, Beijing (CN); Kunpeng ZHANG, Beijing (CN); Xiaona LIU, Beijing (CN); Changjian XU, Beijing (CN)

(21) Appl. No.: 14/446,619

(22) Filed: Jul. 30, 2014

(30) Foreign Application Priority Data
Mar. 7, 2014 (CN) 201410083585.8

(51) Int. Cl. H01L 21/02; H01L 21/67

(52) U.S. Cl. CPC H01L 21/02; H01L 21/67

(57) ABSTRACT

The present invention provides an etching device, which comprises a treatment solution tank for containing treatment solution; and a grabbing unit for putting the substrate in the treatment solution tank and moving the treated substrate out of the treatment solution tank. Accordingly, the present invention further provides an etching method for treating a substrate by using the above etching device. The present invention further provides a patterning apparatus comprising the above etching device. According to the present invention, the uniformity of a reaction between the treatment solution and a corresponding material on the substrate can be improved, and damages which may be caused to the pattern by the existing spray mode can be avoided.

### FIELD OF THE INVENTION

The present invention relates to the field of display technology, in particular to an etching device, an etching method and a patterning apparatus which are used for implementing a patterning process during a manufacturing process of a display device.

### BACKGROUND OF THE INVENTION

In the manufacturing field of semiconductors and display devices, an array substrate is usually manufactured by adopting a patterning process. Here, photoetching treatment in the patterning process usually adopts a wet etching mode in which a developer or etchant is sprayed, that is, the developer (or the etchant is sprayed on a substrate to react with a material to be etched, such as an exposed (or unexposed) photoresist or the like, on the substrate, so as to peel or dissolve the part required to be removed, thus achieving the purpose of etching.

However, it is likely to result in developer residues and particle pollution on the substrate by means of spraying, meanwhile, an impact force during the spraying of the developer may cause damages to the pattern of the photoresist to a certain extent.

### SUMMARY OF THE INVENTION

In view of the above, an object of the present invention is to provide an etching device and an etching method capable of preventing a pattern from damage and preventing particle pollutants from remaining on a substrate during an etching process.

In order to realize the above object, the present invention provides an etching device comprising treatment solution tank, which is used for containing a treatment solution, and a grabbing unit, which is used for putting a substrate into the treatment solution tank and moving the treated substrate out of the treatment solution tank.

Preferably, the treatment solution tank comprises a plurality of treatment solution sub-tanks, and the grabbing unit is capable of moving the substrate from one treatment solution sub-tank to another treatment solution sub-tank.

Preferably, at least one baffle is provided in the treatment solution tank, so as to separate the treatment solution tank into the plurality of treatment solution sub-tanks.

Preferably, the etching device further comprises at least one filter, each of which is used for filtering the treatment solution contained in one treatment solution sub-tank, and then injecting the filtered treatment solution into another treatment solution sub-tank.

Preferably, the etching device further comprises a turnover unit, which is used for turning over the substrate to make a pattern surface of the substrate face downward, the grabbing unit comprises an adsorption member, which is used for adsorbing the other surface of the substrate opposite to the pattern surface.

Preferably, the treatment solution is developer, etchant or deionized water.

Accordingly, the present invention further provides an etching method for treating a substrate by using the etching device provided by the present invention, and the etching method comprises steps of:

S1. soaking, by the grabbing unit, a substrate in treatment solution contained. in the treatment solution tank so as to treat the substrate; and

S2. moving, by the grabbing unit, the treated substrate out of the treatment solution tank.

Preferably, the treatment solution tank comprises a plurality of treatment solution sub-tanks, and the grabbing unit is capable of moving the substrate from one treatment solution sub-tank to another treatment solution sub-tank, and the step S1 comprises:

sequentially soaking the substrate, by the grabbing unit, in treatment solution contained in each of the treatment solution sub-tanks so as to treat the substrate.

Preferably, the etching device further comprises a filter, and after the step S2, the etching method further comprises:

S3. filtering, by the filter, the treatment solution contained in one treatment solution sub-tank, and then injecting the filtered treatment solution into another treatment solution sub-tank.

Preferably, the step S1 comprises: driving, by the grabbing unit, the substrate to reciprocate at a preset rate in a horizontal direction, when the substrate is soaked in the treatment solution.

Preferably, the etching device further comprises a turnover unit, the grabbing unit comprises an adsorption member, and before the step S1, the etching method further comprises:

turning over the substrate by the turnover unit, to make a pattern surface of the substrate face downward, and adsorbing, by the adsorption member, the other surface of the substrate opposite to the pattern surface.

The present invention further provides a patterning apparatus, which comprises the etching device provided by the present invention.

It can be seen that, according to the present invention, by soaking the substrate in the treatment solution contained in the treatment solution tank by using the grabbing unit, the uniformity of a reaction between the treatment solution and a corresponding material on the substrate can be improved, for example, a reaction between the developer and a photoresist, a reaction between the etchant and a corresponding film layer to be etched, or the like, thus avoiding the remain of residues, and avoiding damages which may be caused to the pattern by the existing spray mode. In addition, according to the present invention, the treatment solution can be repeatedly used, thus saving the manufacturing cost.

### BRIEF DESCRIPTION OF THE DRAWINGS

The accompanying drawings, which are used for providing further understanding of the present invention, form a part of the description, and explain the present invention together with the specific implementations below, but not limit the present invention. In the accompanying drawings:

FIG. 1 is a schematic diagram of an example of an etching device provided by an embodiment of the present invention;

FIG. 2 is a schematic diagram of another example of an etching device provided by an embodiment of the present invention;

FIG. 3 is a schematic diagram of still another example of an etching device provided by an embodiment of the present invention; and

FIG. 4 is a flow chart of an etching method provided by an embodiment of the present invention.

### DETAILED DESCRIPTION OF THE EMBODIMENTS

The specific implementations of the present invention will be described in detail below in conjunction with the accompanying drawings. It should be understood that, the specific implementations described herein are used for describing and explaining the present invention only, rather than limiting the present invention.

As an aspect of the present invention, an etching device is provided, as shown in FIGS. 1 to 3, the etching device may comprise a grabbing unit 10 and a treatment solution tank 20. Here, the treatment solution tank 20 is used for treatment solution. The grabbing unit 10 is capable of putting the substrate 11 into the treatment solution tank 20, and capable of moving the substrate 11 that has been treated by the treatment solution out of the treatment solution tank 20.

In the prior art, a corresponding etching process (e.g. developing or corroding) is generally performed on a substrate by means of spraying a treatment solution, the impact force generated by spraying the treatment solution may cause damages to the pattern on the substrate to be treated to a certain extent, the uniformity of the corresponding treatment performed on the substrate by the treatment solution can hardly be ensured, and therefore, particle residues may be generated. In the above etching device provided by the present invention, the substrate 11 to be treated can be put into the treatment solution tank 20 by the grabbing unit 10, so as to be soaked in the treatment solution contained in the treatment solution tank 20 for treating. Compared with the prior art, by using the etching device provided by the present invention to perform an etching treatment, the uniformity of a reaction between a treatment solution and a corresponding material (e.g., a photoresist or a corresponding film layer to be etched) on a substrate can be improved, meanwhile, damages caused to the pattern on the substrate 11 during spraying of the treatment solution are avoided. Moreover, in actual applications, the substrate 11 may keep its pattern surface downward while being soaked in the treatment solution, thus residues or particles resulted from the treatment of the treatment solution can be prevented from remaining on the substrate 11.

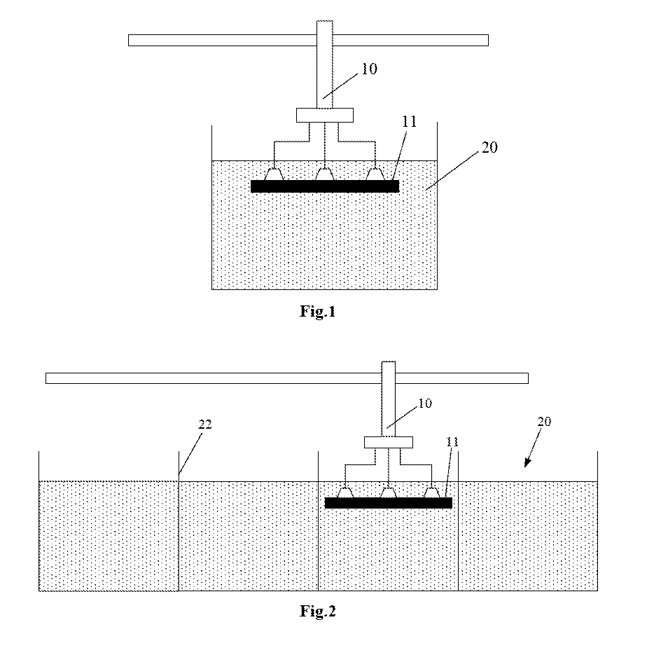

Further, as shown in FIG. 2, the treatment solution tank 20 may comprise a plurality of treatment solution sub-tanks, and the grabbing unit 10 is capable of moving the substrate 11 from one treatment solution sub-tank to another treatment solution sub-tank. In order to achieve a better etching treatment effect, a plurality of treatment solution sub-tanks may be provided, and during treatment, the substrate 11 may be sequentially put in each of the treatment solution sub-tanks by the grabbing unit 10 so as to be treated. The reason why the plurality of treatment solution sub-tanks are provided lies in that, after an etching treatment is performed on the substrate 11 in one treatment solution tank, corresponding residues may be generated in the treatment solution contained in the treatment solution tank, which may influence the subsequent treatment effect. Therefore, with the above structure in which the plurality of treatment solution sub-tanks are provided, after a certain amount of residues is generated in one treatment solution sub-tanks, the substrate 11 may be moved to the next treatment solution sub-tank so as to be treated, thus the treatment effect can be effectively improved. The plurality of treatment solution sub-tanks may be a plurality of separate containers. Or, as shown in FIG. 2, at least one baffle 22 may be provided in the treatment solution tank 20 used as a container, such that the treatment solution tank 20 is separated into the plurality of treatment solution sub-tanks by the baffle 22. The structure in which the at least one baffle 22 is provided in the treatment solution tank 20 to form the plurality of treatment solution sub-tanks is beneficial to saving cost and convenient for machining, and moreover, the plurality of formed treatment solution sub-tanks are sequentially arranged, which helps the grabbing unit 10 to move the substrate 11 from one treatment solution sub-tank to another treatment solution sub-tank.

The number of the treatment solution sub-tanks may be set as required, and this is not limited by the present invention, when the substrate to be treated has a relatively large area, more treatment solution sub-tanks may be provided; and when the substrate to be treated has a relatively small area, fewer treatment solution sub-tanks may be provided.

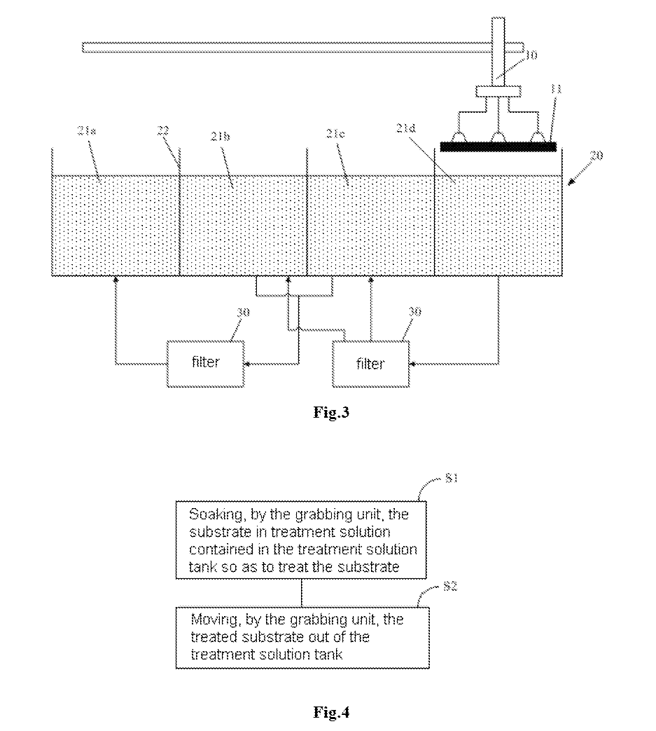

Further, as shown in FIG. 3, the etching device provided by the present invention further comprises at least one filter 30, and the filter 30 is used for filtering the treatment solution in one treatment solution sub-tank, and then injecting the filtered treatment solution into another treatment solution sub-tank. As shown in FIG. 3, because during treatment of the substrate 11, the substrate 11 may be sequentially put into the plurality of treatment solution sub-tanks so as to be treated, for example, the substrate 11 may be sequentially put into the first to the fourth treatment solution sub-tanks 21a-21d from left to right, the later the etching treatment in a treatment solution sub-tank is performed, the fewer the residues generated in the treatment solution sub-tank are. That is to say, the residues generated in the respective treatment solution sub-tanks are gradually reduced from left to right. When the treatment solution in each of the treatment solution sub-tanks needs to be refreshed, the treatment solution in the right treatment solution sub-tank may be filtered by the filter 30 and then be injected. into the left treatment solution sub-tank. For example, in the example shown in FIG. 3, when refreshing the treatment solution in each of the treatment solution sub-tanks, because the amount of the residues of the original treatment solution in the first treatment solution sub-tank 21a is relatively large, the original treatment solution may be directly discharged as waste solution; the original treatment solution in the third treatment solution sub-tank 21c and the second treatment solution sub-tank 21b may be filtered by the filter 30 and then be injected into the first treatment solution sub-tank 21a; the original treatment solution in the fourth treatment solution sub-tank 21d with the fewest residues may be filtered by the filter 30 and then be injected into the third treatment solution sub-tank 21c and the second treatment solution sub-tank 21b; moreover, new treatment solution may be added into the fourth treatment solution sub-tank 21d. With the above mode, the treatment solution can be effectively and repeatedly used, thus saving the cost. Preferably, a pump may be provided in the above filter, such that the filtered treatment solution can be injected into another treatment solution sub-tank.

Further, the etching device provided by the present invention may further comprise a turnover unit, which may be used for turning over the substrate to make the pattern surface of the substrate face downward, the grabbing unit may comprise an adsorption member, which may be used for adsorbing the substrate. Generally, the substrate is placed with its pattern surface facing upward in each process flow, and therefore, before being put into the treatment solution tank, the substrate may be turned over by the turnover unit to make the pattern surface of the substrate face downward. The grabbing unit may comprise an adsorption member used for adsorbing the other surface of the substrate which has been turned over opposite to the pattern surface, such that the substrate may be soaked in the treatment solution contained in the treatment solution tank with the pattern surface facing downward. Specifically, the adsorption member may be implemented by a sucker, and the turnover unit may be implemented by a device such as a manipulator or the like.

Further, the above treatment solution contained in the treatment solution tank may be developer or etchant. That is, a developer may be contained in the treatment solution tank, so as to develop a photoresist on the substrate to form a corresponding pattern; or, an etchant may be contained in the treatment solution tank, so as to etch a corresponding film layer on the substrate to form a corresponding pattern. Of course, the above treatment solution contained in the treatment solution tank may also be deionized water, so as to clean the substrate. For example, after the above developing or etching process is performed on the substrate, the substrate is soaked in the treatment solution tank filled with the deionized water through the grabbing unit, so as to remove the developer or the etchant remained on the substrate, thus realizing cleaning of the substrate, and this process and the developing or etching process may be realized as continuous operation.

As another aspect of the present invention, an etching method is provided, the etching method may treat a substrate by using the etching device provided by the present invention, and as shown in FIG. 4, the etching method may comprise steps of:

S1. soaking, by the grabbing unit, the substrate in treatment solution contained in the treatment solution tank to be subjected to treatment; and

S2. moving, by the grabbing unit, the treated substrate out of the treatment solution tank.

Specifically, the substrate may be put into the treatment solution tank by using the grabbing unit in the above etching device provided by the present invention, and soaked in the treatment solution so as to be treated (such as to be developed or etched) to form the required pattern. After the treatment is finished, the substrate may be moved out of the treatment solution tank by using the grabbing unit.

Further, when the treatment solution tank in the etching device comprises a plurality of treatment solution sub-tanks, and the grabbing unit is capable of moving the substrate from one treatment solution sub-tank to another treatment solution sub-tank, the step S1 comprises:

sequentially soaking, by the grabbing unit, the substrate in treatment solution contained in each of the treatment solution sub-tanks to be subjected to treatment.

That is, the treatment solution tank in the etching device may comprise a plurality of treatment solution sub-tanks, and during treatment, the substrate may be sequentially put into each of the treatment solution sub-tanks by using the grabbing unit, thus being sequentially soaked in a plurality of treatment solutions. The time for soaking the substrate in each of the treatment solution sub-tanks may be set as required, and this is not limited by the present invention.

Further, the etching device may further comprise a filter, and as shown in FIG. 4, after the step S2, the etching method may further comprise:

S3. filtering, by the filter, the treatment solution contained in one of the treatment solution sub-tanks and then injecting the filtered treatment solution into another treatment solution sub-tank.

Specifically, when the treatment solution in each of the treatment solution sub-tanks needs to be refreshed after a certain number of substrates have been treated, the treatment solution contained in one treatment solution sub-tank may be filtered by the filter, and then the filtered treatment solution may be injected into another treatment solution sub-tank, thus the treatment solution in each of the treatment solution sub-tanks can be refreshed. Corresponding to the example shown in FIG. 3, the original treatment solution in the first treatment solution sub-tank 21a with more residues may be directly discharged as waste solution; the original treatment solutions in the third treatment solution sub-tank 21c and the second treatment solution sub-tank 21b may be filtered by the filter 30 and then be injected into the first treatment solution sub-tank 21a; the original treatment solution in the fourth treatment solution sub-tank 21d with the fewest residues may be filtered by the filter 30 and then be injected into the third treatment solution sub-tank 21c and the second treatment solution sub-tank 21b; moreover, new treatment solution may be added into the fourth treatment solution sub-tank 21d.

Further, in the above step S1, when the substrate is soaked in the treatment solution, the substrate may be driven by using the grabbing unit to reciprocate at a preset rate in the horizontal direction. Specifically, when the substrate is soaked in the treatment solution, the substrate may be driven by using the grabbing unit to reciprocate at a preset rate in the horizontal direction, which facilitates adequate reaction between the treatment solution and the corresponding material (the photoresist or the corresponding film layer) on the substrate, and facilitates the failing-off of the generated residues. The rate at which the substrate is driven to reciprocate may be set as required, and preferably, the rate may be set at 3 cm/s to 6 cm/s.

Further, the etching device may further comprise a slide guide rail suspended above the treatment solution tank and extending along the horizontal direction, and the grabbing unit 10 may be matched onto the slide guide rail. By enabling the grabbing unit 10 to slide along the extending direction of the slide guide rail and to stretch in the vertical direction, the following actions may be achieved by the grabbing unit 10: putting the substrate in the treatment solution tank or moving the substrate out of the treatment solution tank, moving the substrate from one treatment solution sub-tank to another treatment solution sub-tank, and driving the substrate to reciprocate in the treatment solution tank. Of course, in order to realize the above actions, the etching device may further comprise a power component and a control component.

Further, the above etching device may further comprise a turnover unit, and the grabbing unit may comprise an adsorption member, before the step S1 is performed, the substrate may be turned over by using the turnover unit to make the pattern surface of the substrate face downward, and the other surface of the substrate opposite to the pattern surface is adsorbed by using the adsorption member.

That is, when the corresponding treatment is performed by using the etching device, if the pattern surface of the substrate faces upward, the substrate may be turned over by the turnover unit to make the pattern surface of the substrate face downward, and then the other surface of the substrate opposite to the pattern surface is adsorbed by using the adsorption member on the grabbing unit, such that the pattern surface of the substrate faces downward when the substrate is soaked in the treatment solution.

As still another aspect of the present invention, a patterning apparatus is provided, and the patterning apparatus comprises the etching device provided by the present invention.

The etching device, the etching method and the patterning apparatus provided by the present invention have been described above, it can be seen that, according to the present invention, by soaking the substrate in treatment solution contained in the treatment solution tank by using the grabbing unit, the uniformity of a reaction between the treatment solution and a corresponding material on the substrate can be improved, thus preventing the residues from remaining on the substrate, and avoiding damages which may be caused to the pattern by the existing spray mode. In addition, according to the present invention, the treatment solution can be repeatedly used, thus saving the cost.

It may be understood that, the foregoing implementations are merely exemplary implementations adopted for illustrating the principle of the present invention, but the present invention is not limited thereto. Various variations and improvements could be made by those skilled in the art without departing from the spirit and essence of the present invention, and these variations and improvements are also deemed as the protection scope of the present invention.

1. An etching device, comprising a treatment solution tank, which is used for containing treatment solution; and a grabbing unit, which is used for putting a substrate into the treatment solution tank, and moving the treated substrate out of the treatment solution tank.

2. The etching device according to claim 1, wherein the treatment solution tank comprises a plurality of treatment solution sub-tanks, and the grabbing unit is used for moving the substrate from one treatment solution sub-tank to another treatment solution sub-tank.

3. The etching device according to claim 2, wherein at least one baffle is provided in the treatment solution tank, so as to separate the treatment solution tank into the plurality of treatment solution sub-tanks.

4. The etching device according to claim 2, further comprising at least one filter, each of Which is used for filtering the treatment solution contained in one treatment solution sub-tank, and then injecting the filtered treatment solution into another treatment solution sub-tank.

5. The etching device according to claim 1, further comprising a turnover unit, which is used for turning over the substrate to make a pattern surface of the substrate face downward, wherein the grabbing unit comprises an adsorption member which is used for adsorbing the other surface of the substrate opposite to the pattern surface.

6. The etching device according to claim 2, further comprising a turnover unit, which is used for turning over the substrate to make a pattern surface of the substrate face downward, wherein the grabbing unit comprises an adsorption member, which is used for adsorbing the other surface of the substrate opposite to the pattern surface.

7. The etching device according to claim 3, further comprising a turnover unit, which is used for turning over the substrate to make a pattern surface of the substrate face downward, wherein the grabbing unit comprises an adsorption member, which is used for adsorbing the other surface of the substrate opposite to the pattern surface.

8. The etching device according to claim 4, further comprising a turnover unit, which is used for turning over the substrate to make a pattern surface of the substrate face downward, wherein the grabbing unit comprises an adsorption member, which is used for adsorbing the other surface of the substrate opposite to the pattern surface.

9. The etching device according to claim 1, wherein the treatment solution is developer, etchant or deionized water.

10. An etching method for treating a substrate by using an etching device, wherein the etching device comprises a treatment solution tank, which is used for containing treatment solution; and a grabbing unit, which is used for grabbing and moving a substrate, and the etching method comprises steps of:
S1. soaking, by the grabbing unit, the substrate in the treatment solution contained in the treatment solution tank so as to treat the substrate; and
S2. moving, by the grabbing unit, the treated substrate out of the treatment solution tank.

11. The etching method according to claim 10, wherein the treatment solution tank comprises a plurality of treatment solution sub-tanks, the grabbing unit is used for moving the substrate from one treatment solution sub-tank to another treatment solution sub-tank, and the step S1 comprises:
sequentially soaking, by the grabbing unit, the substrate in the treatment solution contained in each of the treatment solution sub-tanks so as to treat the substrate.

12. The method according to claim 11, wherein the etching device further comprises a filter, and after the step S2, the etching method further comprises:
S3. filtering, by the filter, the treatment solution contained in one treatment solution sub-tank, and then injecting the filtered treatment solution into another treatment solution sub-tank.

13. The method according to claim 10, wherein the step S1 comprises: when the substrate is soaked in the treatment solution, driving the substrate by the grabbing unit to reciprocate at a preset rate in a horizontal direction.

14. The method according to claim 11, wherein the step S1 comprises: when the substrate is soaked in the treatment solution, driving the substrate by the grabbing unit to reciprocate at a preset rate in a horizontal direction.

15. The method according to claim 12, wherein the step S1 comprises: when the substrate is soaked in the treatment solution, driving the substrate by the grabbing unit to reciprocate at a preset rate in a horizontal direction.

16. The method according to claim 10, wherein the etching device further comprises a turnover unit, the grabbing unit comprises an adsorption member, and before the step S1, the etching method further comprises:
turning over the substrate by the turnover unit to make a pattern surface of the substrate face downward, and adsorbing, by the adsorption member, the other surface of the substrate opposite to the pattern surface.

17. The method according to claim 11, wherein the etching device further comprises a turnover unit, the grabbing unit comprises an adsorption member, and before the step S1, the etching method further comprises:
turning over the substrate by the turnover unit to make a pattern surface of the substrate face downward, and adsorbing, by the adsorption member, the other surface of the substrate opposite to the pattern surface.

18. The method according to claim 12, wherein the etching device further comprises a turnover unit, the grabbing, unit comprises an adsorption member, and before the step S1, the etching method further comprises:
turning over the substrate by the turnover unit to make a pattern surface of the substrate face downward, and adsorbing, by the adsorption member, the other surface of the substrate opposite to the pattern surface.

19. A patterning apparatus, comprising the etching device according to claim 1.
